(19) United States
(12) Patent Application Publication
(10) Pub. No.: US 2010/0019664 A1
(43) Pub. Date: Jan. 28, 2010

(54) ORGANIC ELECTROLUMINESCENCE PANEL AND A METHOD FOR MANUFACTURING THE SAME

(75) Inventor: Masayuki MISHIMA, Kanagawa (JP)

Correspondence Address: Solaris Intellectual Property Group, PLLC, 401 Holland Lane, Suite 407, Alexandria, VA, 22314, US

(73) Assignee: FUJIFILM CORPORATION, Tokyo (JP)

(21) Appl. No.: 12/500,623

(22) Filed: Jul. 10, 2009

(30) Foreign Application Priority Data
Jul. 22, 2008 (JP) 2008-188376

(51) Int. Cl. H01J 1/62; C23C 14/34

(52) U.S. Cl. 313/504; 204/192.1

(57) ABSTRACT

An organic electroluminescence panel comprises a supporting substrate, a lower electrode, an organic layer including at least a luminescence layer, an upper electrode, an inorganic layer which has a refractive index in the range of 1.7 to 3.0 and which has a concave-convex structure having a surface roughness of 10 to 10 μm formed at an outermost surface on a light extraction side, an adhesive layer, and a light extraction substrate formed therein in this order. Preferably, the inorganic layer comprises plural layers, a layer including the outermost surface at the light extraction side is a high-refractive-index layer having a refractive index of 2.1 to 3.0, and at least one of the other layers among the plural layers is a gas barrier layer having higher gas barrier properties than those of the high-refractive-index layer.

### CROSS REFERENCE TO RELATED APPLICATION

This application claims priority under 35USC 119 from Japanese Patent Application No. 2008-188376 filed on Jul. 22, 2008, the disclosure of which is incorporated herein by reference.

### BACKGROUND OF THE INVENTION

1. Field of the Invention

The present invention relates to an organic electroluminescence panel and a method for manufacturing the same.

2. Description of the Related Art

In recent years, a luminescent device using an organic electroluminescence element (also referred to hereinafter as organic EL element) has been developed. For example, a lower electrode, an organic electroluminescence (EL) layer including at least a luminescent layer, and an upper electrode are layered in this order on a supporting substrate such as glass, and then sealed with a sealing substrate such as glass to protect the organic EL element against oxygen or moisture in the air. The organic EL element is connected via lead-out lines (terminals) of both electrodes to external lines through which an electric field is applied to the element, whereby a hole and an electron are recombined with each other to emit light in a luminescent layer in a region sandwiched between the electrodes.

In devices equipped with such an organic electroluminescence element, there are generally a bottom emission-type device for extracting light generated in a luminescent layer, from the side of a supporting substrate, and a top emission-type device for extracting light from a sealing substrate, and for either type, it has been proposed to arrange a light scattering layer or the like at the light extraction side in order to increase the efficiency of extraction of light from the luminescent layer.

For example, an organic EL multicolor display panel provided at the light extraction side thereof with a light scattering layer having light scattering particles such as alumina dispersed in resin has been proposed (see Japanese Patent Application Laid-Open (JP-A) No. 2007-273397).

It has also been proposed to provide a high-refractive-index layer and a transparent substrate at the light extraction side of an electroluminescence layer, and further provide light scattering layers having particles such as titanium oxide dispersed in a thermosetting resin or the like on the respective light extraction sides of the high-refractive index layer and the transparent substrate, or form unevenness at the respective light extraction sides thereof by blasting treatment, thereby conferring a light scattering function (see JP-A No. 2006-286616).

### SUMMARY OF THE INVENTION

The present invention has been made in view of the above circumstances and provides the following organic electroluminescence panel and a method for manufacturing the same.

According to a first aspect of the invention, an organic electroluminescence panel is provided, which includes:

a supporting substrate,

a lower electrode arranged on the supporting substrate,

an organic layer arranged on the lower electrode and including at least a luminescence layer,

an upper electrode arranged on the organic layer,

an inorganic layer which is arranged on the upper electrode, has a refractive index in the range of 1.7 to 3.0, and has a concave-convex structure having a surface roughness Ra of 10 nm to 10 μm formed at an outermost surface on a light extraction side,

an adhesive layer arranged on the inorganic layer, and

a light extraction substrate adhered via the adhesive layer to the inorganic layer.

According to a second aspect of the invention, a method for manufacturing the organic electroluminescence panel of the first aspect of the invention is provided, which includes:

forming an inorganic film on the upper electrode, and

sputtering the outermost surface, at the light extraction side, of the inorganic film, thereby providing the outermost surface with a concave-convex structure.

### BRIEF DESCRIPTION OF THE DRAWINGS

FIG. 1 is a schematic diagram showing one example of the structure of the organic electroluminescence panel of the present invention.

FIG. 2 is a schematic diagram showing one example of the structure of an inorganic layer.

### DETAILED DESCRIPTION OF THE INVENTION

Hereinafter, the organic electroluminescence panel of the present invention and a method for manufacturing the same will be described with reference to the accompanying drawings.

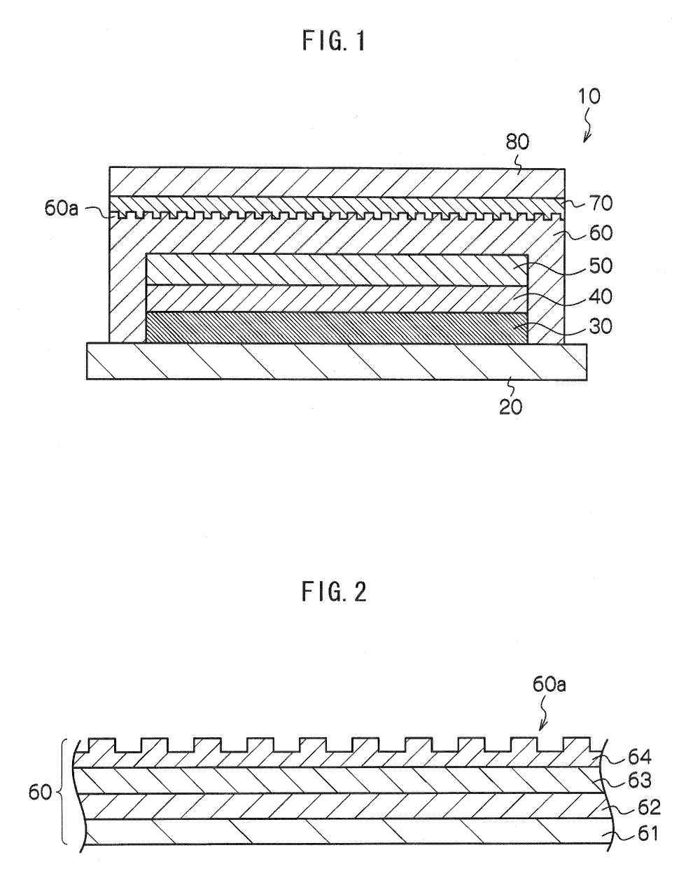

FIG. 1 schematically shows the structure of the luminescence panel of the invention. The organic electroluminescence panel 10 includes a supporting substrate 20, a lower electrode 30 arranged on the supporting substrate 20, an organic layer 40 arranged on the lower electrode 30 and including at least a luminescence layer, an upper electrode 50 arranged on the organic layer 40, an inorganic layer 60 arranged on the upper electrode 50, an adhesive layer 70 arranged on the inorganic layer 60, and a light extraction substrate 80 adhered via the adhesive layer 70 to the inorganic layer 60. The inorganic layer 60 has a refractive index in the range of 1.7 to 3.0 and has a concave-convex structure 60a formed at an outermost surface thereof at a light extraction side, and the surface roughness Ra thereof is 10 nm to 10 μm.

Light generated in the luminescent layer contained in the organic layer 40 is extracted via the upper electrode 50, the inorganic layer 60, the adhesive layer 70, and the light extraction substrate 80 to the outside. In the organic electroluminescence panel 10, an inorganic layer 60 can function as a sealing layer and a light scattering layer to show high light extraction efficiency.

Hereinafter, the constituent members and the manufacturing method will be described.

### <Supporting Substrate>

The supporting substrate 20 is a substrate having strength to support an organic EL element formed thereon. Examples of the material thereof include inorganic materials such as zirconia stabilized yttrium (YSZ), and glass; and organic materials such as, polyester such as polyethylene terephthalate, polybutylene phthalate, polyethylene naphthalate and the like, polystyrene, polycarbonate, polyethersulfone, polyarylate, polyimide, polycycloolefin, norbornene resin, and poly(chlorotrifluoroethylene).

When a substrate made of glass is used as the supporting substrate 20, the glass is preferably non-alkali glass in order to decrease ions eluted from the glass. When soda lime glass is used, it is preferred to provide a barrier coat such as silica on the glass.

In the case of using the supporting substrate 20 made of an organic material, it is preferred that the substrate 20 is excellent in heat resistance, dimension stability, solvent resistance, electric non-conductance and workability. In the case of using, in particular, a plastic supporting substrate 20, it is preferred to form a moisture permeation preventing layer or a gas barrier layer onto one side or both sides of the supporting substrate 20 in order to restrain the permeation of moisture or oxygen. The material of the moisture permeation preventing layer or the gas barrier layer is preferably an inorganic material such as silicon nitride, silicon oxide, silicon oxynitride, or aluminum oxide, or a laminate composed of two or more selected from the inorganic materials and organic materials such as acrylic resin. The moisture permeation preventing layer or the gas barrier layer may be formed by, for example, high-frequency sputtering.

In the case of using a thermoplastic supporting substrate, a hard coat layer, an undercoat layer or the like may be formed thereon as the need arises.

The shape, the structure, the size and other characters of the supporting substrate 20 are not particularly limited, and these may be appropriately selected in accordance with the use manner and the use purpose of the organic EL element. In general, the shape of the supporting substrate 20 is preferably a plate-like shape from the viewpoint of the handleability and the easiness of formation of the organic EL element. The structure of the supporting substrate 20 may be a monolayer structure or a layered structure. The supporting substrate 20 may be made of a single member, or two or more members.

The organic electroluminescence panel 10 of the invention is a top emission-type device and does not require emitted light to be extracted via the side of the supporting substrate 20, and thus the supporting substrate may be a metal substrate of stainless steel, Fe, Al, Ni, Co, Cu or an alloy thereof, or a silicon substrate. The supporting substrate made of a metal has high strength and high gas barrier properties against moisture and oxygen in the air, even if the substrate is thin. When the metallic supporting substrate is used, an insulating film for securing electrical insulation properties may be disposed between the supporting substrate 20 and the lower electrode 30.

### <Electrodes>

One of the lower electrode 30 and the upper electrode 50 is used as an anode and the other as a cathode. The electrodes 30 and 50 are arranged to face each other via the organic layer 40 including at least a luminescent layer, and an electric field is applied between the electrodes 30 and 50, thereby allowing the luminescent layer sandwiched between the electrodes 30 and 50 to emit light. Because light in the luminescent layer is extracted from the side of the upper electrode 50, at least the upper electrode 50 is formed using an electrode material and thickness selected so as to be transparent to light from the luminescent layer. The light transmittance of the upper electrode 50 is preferably 60% or more, more preferably 70% or more. The lower electrode 30, on the other hand, is not required to be transparent to light from the luminescent layer and preferably has light reflectivity.

—Anode—

The anode is not particularly limited about the shape, the structure, the size and other characters as long as the anode is a member having a function of an electrode for supplying holes to the organic EL layer. The anode may be appropriately selected from known electrode materials in accordance with the use manner and the use purpose of the organic EL element.

Preferred examples of the material which constitutes the anode include metals, alloys, metal oxides, electroconductive compounds, and mixtures thereof. Specific examples thereof include electroconductive metal oxides such as tin oxide doped with antimony or fluorine (ATO, or FTO), tin oxide, zinc oxide, indium oxide, indium tin oxide (ITO), and indium zinc oxide (IZO); metals such as gold, silver, chromium, and nickel; mixtures or laminates each composed of two or more selected from the metals and the electroconductive metal oxides; electroconductive inorganic materials such as copper iodide and copper sulfide; electroconductive organic materials such as polyaniline, polythiophene, and polypyrrole; and laminates each composed of one or more selected from these materials, and ITO.

The upper electrode 50, when used as an anode in the luminescence panel 10 of the invention, is preferably constituted of a highly optically transparent material, because light emitted from the luminescent layer is extracted from the side of the upper electrode 50. Preferable among the materials described above is an electroconductive metal oxide, particularly preferably ITO, from the viewpoint of productivity, high electric conductivity, transparency.

Examples of the method for forming the anode include wet methods such as printing and coating methods; physical methods such as vacuum deposition, sputtering, and ion plating; and chemical methods such as CVD and plasma CVD. The method may be appropriately selected, considering suitability for the material which constitutes the anode. When ITO is used as the anode material, for example, the anode may be formed by direct current or high frequency sputtering, vacuum deposition, ion plating or the like.

The position in which the anode is to be formed can be selected appropriately depending on the use, object etc. of the organic EL element. The lower electrode 30 when used as the anode may be formed wholly or partially on the supporting substrate 20, or the upper electrode 50 when used as the anode may be formed wholly or partially on the organic layer 40.

When the anode is formed, patterning may be performed by chemical etching based on photolithography or the like, or by physical etching using a laser or the like. The patterning may be performed by vacuum vapor deposition, sputtering or the like via a mask superimposed on the substrate. The patterning may be performed by a liftoff method or a printing method.

The thickness of the anode may be appropriately selected in accordance with the material which constitutes the anode, and is usually from about 10 nm to 50 μm, preferably from 50 nm to 20 μm.

The resistivity of the anode is preferably from 10³ Ω/□ or less, more preferably 10² Ω/□ or less in order to supply holes certainly to the organic EL layer 40.

Transparent anodes are described in detail in “New Development of Transparent Electrode Films”, supervised by Yutaka Sawada, published by CMC Publishing Co., Ltd. (1999). Matters described therein may be applied to the invention. In the case of using, for example, a low heat-resistant supporting substrate made of a plastic, ITO or IZO is used. A transparent anodes made into a film form at a low temperature of 150° C. or lower is preferred.

—Cathode—

The cathode usually has an electrode function of supplying electrons to the organic EL layer 40, and is not particularly limited about the shape, the structure, the size. The cathode may be appropriately selected from known electrodes in accordance with the use manner and the use purpose of the organic EL display device 10. Examples of the material which constitutes the cathode include metals, alloys, metal oxides, electroconductive compounds, and mixtures thereof. Specific examples include alkali metals (such as Li, Na, K and Cs), alkaline earth metals (such as Mg, and Ca), gold, silver, lead, aluminum, sodium-potassium alloy, lithium-aluminum alloy, magnesium-silver alloy, and rare earth metals such as indium, and ytterbium. These may be used alone. In order to make the stability and the electron-injecting performance of the cathode compatible with each other, they are preferably used in combination of two or more thereof.

Of these materials, alkali metals or alkaline earth metals are preferred as the material which constitutes the cathode from the viewpoint of electron injecting performance. From the viewpoint of excellent storage stability, a material made mainly of aluminum is preferred. The material made mainly of aluminum is aluminum alone, an alloy composed of aluminum and 0.01 to 10% by mass of an alkali metal or alkaline earth metal, or a mixture composed of aluminum and such a metal (for example, lithium-aluminum alloy or magnesium-aluminum alloy). The material of the cathode is described in detail in, for example, JP-A Nos. 2-15595 and 5-121172. The materials described in these publications may be used in the invention.

The method for forming the cathode is not particularly limited. Thus, the cathode may be formed by a known method. The cathode may be formed by a method selected appropriately from wet methods such as printing and coating methods, physical methods such as vacuum vapor deposition, sputtering, and ion plating, chemical methods such as CVD and plasma CVD, considering suitability for the material which constitutes the cathode. In the case of selecting, for example, a metal as the material of the cathode, the cathode may be formed, for example, by sputtering a single species, or sputtering two or more species simultaneously or successively.

The thickness of the cathode may be appropriately selected in accordance with the material which constitutes the cathode or the light extraction direction. The thickness is usually from about 1 nm to 5 μm.

When the cathode is formed, patterning may be performed by chemical etching based on photolithography or the like, or by physical etching using a laser or the like. The patterning may be performed by vacuum vapor deposition, sputtering or the like via a mask superimposed on the substrate. The patterning may be performed by a liftoff method or a printing method.

The position in which the cathode is to be formed is not particularly limited. The lower electrode 30 when used as the cathode may be formed wholly or partially on the supporting substrate 20, or the upper electrode 50 when used as the cathode may be formed wholly or partially on the organic layer 40.

A dielectric layer made of a fluoride of an alkali metal or alkaline earth metal, an oxide thereof, or the like may be formed at a thickness of 0.1 to 5 nm between the cathode and the organic EL layer 40. This dielectric layer may be regarded as a kind of electron injection layer. The dielectric layer may be formed by, for example, vacuum vapor deposition, sputtering, or ion plating.

### <Organic Layer>

The organic layer 40 contains at least a luminescent layer and is arranged between the lower electrode 30 and the upper electrode 50.

The organic EL element including an anode, an organic layer and a cathode may employ, for example, any of layer structures as described in the following, but not limited to these, and may be appropriately determined in accordance with the purpose or the like.
Anode/luminescent layer/cathode
Anode/hole transport layer/luminescent layer/electron transport layer/cathode
Anode/hole transport layer/luminescent layer/block layer/electron transport layer/cathode
Anode/hole transport layer/luminescent layer/block layer/electron transport layer/electron injection layer/cathode
Anode/hole injection layer/hole transport layer/luminescent layer/block layer/electron transport layer/cathode
Anode/hole injection layer/hole transport layer/luminescent layer/block layer/electron transport layer/electron injection layer/cathode
Anode/hole transport layer/block layer/luminescent layer/electron transport layer/cathode
Anode/hole transport layer/block layer/luminescent layer/electron transport layer/electron injection layer/cathode
Anode/hole injection layer/hole transport layer/block layer/luminescent layer/electron transport layer/cathode
Anode/hole injection layer/hole transport layer/block layer/luminescent layer/electron transport layer/electron injection layer/cathode

In any of the layer structures, overlapping regions of the lower electrode 30, the organic layer 40 and the upper electrode 50 emit light. Accordingly, a luminescent layer corresponding to each color is patterned such that for example, R, G and B pixels are arrayed lengthwise and crosswise on the supporting substrate 20, thereby enabling full-color display.

Examples of the layers other than the luminescent layer, which constitute the organic layer 40, include layers such as a hole transport layer, an electron transport layer, a charge block layer, a hole injection layer and an electron injection layer as described above. In a preferable mode, the layer structure comprises, for example, a hole transport layer, a luminescent layer and an electron transport layer formed in this order from the side of an anode and may further have, for example, a charge block layer or the like between the hole transport layer and the luminescent layer or between the luminescent layer and the electron transport layer. The layer structure may have a hole injection layer between an anode and a hole transport layer or may have an electron injection layer between a cathode and an electron transport layer. Each of the layers may be divided into plural secondary layers.

The layers constituting the organic layer 40 may be formed by a film-forming method selected from dry methods such as vapor deposition and sputtering, a transfer method, a print method and the like.

Material and thickness of each layer constituting the organic layer 40 are not particularly limited and can be selected from those known in the art.

### —Luminescent Layer—

The luminescent layer may be formed of a luminescence material only or may be formed of a mixed layer of a host material and a luminescence material. The luminescence material may be a fluorescence or phosphorescence material and may contain one or more dopants. The host material is preferably a charge transport material. The luminescent layer may contain one or more host materials which may be constituted, for example, of a mixture of an electron-transporting host material and a hole-transporting host material. The luminescent layer may contain a non-luminescent material not having an ability to transport charge.

The luminescent layer may be composed of one or more layers which may emit lights having luminescent colors different from one another.

Examples of the fluorescence material include benzoxazol derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, condensed aromatic compounds, perynone derivatives, oxadiazole derivatives, oxazine derivatives, aldazine derivatives, pyralidine derivatives, cyclopentadiene derivatives, bisstyrylanthracene derivatives, quinacridon derivatives, pyrrolopyridine derivatives, thiadiazolopyridine derivatives, cyclopentadiene derivatives, styrylamine derivatives, diketopyrrolopyrrole derivatives, aromatic dimethylidyne compounds, various metal complexes, typical examples of which include metal complexes of an 8-quinolinol derivative, and metal complexes of a pyrromethene derivative, polymeric compounds such as polythiophene, polyphenylene and polyphenylenevinylene, and organic silane derivatives.

Examples of the phosphorescence material include complexes each containing a transition metal atom or a lanthanoid atom.

The transition metal atom is not particularly limited, and is preferably ruthenium, rhodium, palladium, tungsten, rhenium, osmium, iridium, or platinum, more preferably rhenium, iridium or platinum.

Examples of the lanthanoid atom include lanthanum, cerium, praseodymium, neodymium, samarium, europium, gadolinium, terbium, dysprosium, holmium, erbium, thulium, ytterbium, and lutetium. Of these lanthanoid atoms, neodymium, europium and gadolinium are preferred.

Examples of the ligand of the complexes include ligands described in G. Wilkinson et al., “Comprehensive Coordination Chemistry”, published by Pergamon Press Co. in 1987; H. Yersin, “Photochemistry and Photophysics of Coordination Compounds”, published by Springer-Verlag Co. in 1987; and Akio Yamamoto, “Organometallic Chemistry —Foundation and Application—”, published by Shokabo Publishing Co., Ltd. in 1982.

Preferred specific examples of the ligand include halogen ligands (preferably, a chlorine ligand), nitrogen-containing heterocyclic ligands (such as phenylpyridine, benzoquinoline, quinolinol, bipyridyl, and phenanthroline), diketone ligands (such as acetylacetone), carboxylic acid ligands (such as an acetic acid ligand), a carbon monoxide ligand, an isonitrile ligand, and a cyano ligand. More preferred are nitrogen-containing heterocyclic ligands. The above-mentioned complexes may each have a single transition metal atom in the compound thereof, or may each be a multi-nucleus complex, which has two or more transition metal atoms. The multi-nucleus complex may have different metal atoms simultaneously.

The phosphorescence material is contained in the luminescence layer preferably in a proportion of 0.1 to 40% by mass of the layer, more preferably in a proportion of 0.5 to 20% by mass thereof.

Specific examples of the host material contained in the luminescence layer include materials having a carbazole skeleton, materials having a diarylamine skeleton, materials having a pyridine skeleton, materials having a pyrazine skeleton, materials having a triazine skeleton, materials having an arylsilane skeleton, and materials exemplified in items “hole injection layer and hole transport layer”, and “electron injection layer and electron transport layer”, which will be described later.

The thickness of the luminescence layer is not particularly limited. Usually, the thickness is preferably from 1 to 500 nm, more preferably from 5 to 200 nm, even more preferably from 10 to 100 nm.

—Hole Injection Layer and Hole Transport Layer—

The hole injection layer and the hole transport layer are each layer having a function of receiving holes from the anode or the anode side and transporting the holes to the cathode side thereof. Specifically, the hole injection layer and the hole transport layer are each preferably a layer containing one or more selected from carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazane derivatives, aromatic tertiary amine compounds, styrylamine compounds, aromatic dimethylidene compounds, porphyrin compounds, organic silane derivatives, carbon, and various metal complexes, typical examples of which include Ir complexes each having phenylazole or phenylazine as a ligand.

The thickness of each of the hole injection layer and the hole transport layer is preferably 500 nm or less in order to make the driving voltage low.

The thickness of the hole transport layer is preferably from 1 to 500 nm, more preferably from 5 to 200 nm, even more preferably from 10 to 200 nm. The thickness of the hole injection layer is preferably from 0.1 to 200 nm, more preferably from 0.5 to 200 nm, even more preferably from 1 to 200 nm.

The hole injection layer and the hole transport layer may each have a monolayer structure made of one or more selected from the above-mentioned materials, or a multilayered structure composed of plural secondary layers which have the same composition or different compositions.

—Electron Injection Layer and Electron Transport Layer—

The electron injection layer and the electron transport layer are each a layer having a function of receiving electrons from the cathode or the cathode side and transporting the electrons to the anode side. Specifically, the electron injection layer and the electron transport layer are each preferably a layer containing one or more selected from triazole derivatives, oxazole derivatives, oxadiazole derivatives, imidazole derivatives, fluorenone derivatives, anthraquinodimethane derivatives, anthrone derivatives, diphenylquinone derivatives, thiopyrandioxide derivatives, carbodiimide derivatives, fluorenylidenemethane derivatives, distyrylpyrazine derivatives, aromatic ring tetracarboxylic acid anhydrides such as naphthalene and perylene, phthalocyanine derivatives, various metal complexes, typical examples of which include metal complexes of an 8-quinolinol derivative, metal phthalocyanines, and metal complexes each having benzoxazole or benzothiazole as a ligand, organic silane derivatives.

The thickness of each of the electron injection layer and the electron transport layer is preferably 500 nm or less in order to make the driving voltage low.

The thickness of the electron transport layer is preferably from 1 to 500 nm, more preferably from 5 to 200 nm, even more preferably from 10 to 100 nm. The thickness of the electron injection layer is preferably from 0.1 to 200 nm, more preferably from 0.2 to 100 nm, even more preferably from 0.5 to 50 nm.

The electron injection layer and the electron transport layer may each have a monolayer structure made of one or more selected from the above-mentioned materials, or a multilayered structure composed of plural secondary layers which have the same composition or different compositions.

—Hole Block Layer—

The hole block layer is a layer having a function of preventing holes transported from the anode side to the luminescence layer from going through to the cathode side. The hole block layer adjacent to the luminescence layer at the cathode side thereof may be formed.

The hole block layer may be made of an organic compound, and examples thereof include aluminum complexes such as BAlq, triazole derivatives, and phenanthroline derivatives such as BCP.

The thickness of the hole block layer is preferably from 1 to 500 nm, more preferably from 5 to 200 nm, even more preferably from 10 to 100 nm.

The hole block layer may have a monolayer structure made of one or more selected from the above-mentioned materials, or a multilayered structure composed of plural secondary layers which have the same composition or different compositions.

### <Inorganic Layer>

The inorganic layer 60 is disposed on the upper electrode 50 and provided with a concave-convex structure 60a formed at the outermost surface thereof at the light extraction side so that the surface roughness Ra thereof is 10 nm to 10 μm. The inorganic layer 60 is formed of an inorganic material having a refractive index of 1.7 to 3.0, preferably 1.7 to 2.6. Specific examples of the inorganic material include silicon nitride, silicon oxide, silicon oxynitride, aluminum oxide, titanium oxide, and zinc sulfide.

The method of forming the inorganic layer 60 is not particularly limited. For example, the inorganic layer is formed by making a film of the above-mentioned inorganic material by a physical method such as vacuum deposition, sputtering or ion plating or a chemical method such as CVD or plasma CVD.

The inorganic layer 60 may be formed so as to cover at least the surface, at the light extraction side, of the upper electrode 50, but is preferably formed so as to also cover the side surfaces of the electrodes 30 and 50 and the organic layer 40 as shown in FIG. 1, in order to improve the light extraction efficiency and to effectively prevent deterioration of the electrodes 30 and 50 and the organic layer 40 due to oxygen and moisture in the air.

The outermost surface, at the light extraction side, of the inorganic layer 60 thus formed can be subjected to sputtering (so-called reverse sputtering), etching or the like to provide the outermost surface with a concave-convex structure. Particularly from the viewpoint of protecting the lower organic EL layer, it is preferable that the outermost surface of the inorganic layer 60 is sputtered to provide it with the concave-convex structure 60a. The reaction gas used in sputtering the outermost surface of the inorganic layer 60 may be, for example, an argon gas, a nitrogen gas or the like.

The inorganic layer 60 is not limited to one layer and may be constituted by forming plural inorganic layers different in characteristics such as sealing characteristics (gas barrier properties), light extraction characteristics (optical transparency and light scattering property), and stress relaxation characteristics. Among plural layers constituting the inorganic layer, for example, if a layer including the outermost surface at the light extraction side is made to be a high-refractive-index layer having a high refractive index, and at least one of the other layers is made to be a gas barrier layer having higher gas barrier properties than those of the high-refractive-index layer at the outermost surface, a light emitting panel reliably excellent in both light extraction characteristics and sealing characteristics can be obtained.

All of the inorganic layers have a refractive index in the range of 1.7 to 3.0. However, for further improving the light extraction efficiency, the refractive index of the inorganic layer including the outermost surface at the light extraction side is preferably higher, and the high-refractive-index layer has a refractive index preferably in the range of 2.1 to 3.0. For example, the inorganic layer at the outermost surface at the light extraction side, when formed of TiO₂ or ZnS, is advantageous not only in that the refractive index is high and the light extraction efficiency is further improved, but also in that after formation, the layer can be easily subjected to concave-convex processing by sputtering.

The gas barrier layer is preferably formed of SiON or SiN, from the viewpoint of denseness and gas barrier properties.

FIG. 2 schematically shows one example of the inorganic layer 60 constituted of plural layers 61, 62, 63 and 64 which are different from one another in characteristics. For example, the layer 61 formed of SiN (refractive index: 2.0) having high sealing characteristics, the layer 62 formed of SiON (refractive index: 1.7 to 1.8) having high stress relaxation characteristics, the layer 63 formed of SiN (refractive index: 2.0) having high sealing characteristics, and the layer 64 formed of TiO₂ or ZnS (refractive index: 2.4 to 2.6) having a high refractive index are formed in this order, and the concave-convex structure 60a is formed at the outermost surface.

In this way, plural layers 61, 62, 63 and 64 are formed to constitute the inorganic layer 60 by using the inorganic materials each having a refractive index in the range of 1.7 to 3.0 and being different in characteristics, and its outermost surface at the light extraction side is provided with concaveconvexity by sputtering or the like, whereby both sealing characteristics and light extraction characteristics can be improved more reliably. As the material having a high refractive index, barium titanate (refractive index: 2.4) or strontium titanate (refractive index: 2.37) can be used besides TiO₂ and ZnS mentioned above.

From the viewpoint of reliably exhibiting both sealing characteristics and light extraction characteristics, the thickness (total thickness) of the inorganic layer 60 is preferably 0.1 to 20 μm, more preferably 1 to 10 μm, even more preferably 2 to 7 μm.

From the viewpoint of extracting light more efficiently, the surface roughness Ra of the concave-convex structure at the outermost surface, at the light extraction side, of the inorganic layer 60 is 10 nm to 10 μm, preferably 10 nm to 5 μm, more preferably 50 nm to 2 μm. The surface roughness Ra is a value determined in accordance with JIS B0601:2001 by using a P-15 contact-type surface roughness meter manufactured by KLA-Tencor Japan.

### <Adhesive Layer>

The light extraction substrate 80 is adhered via the adhesive layer 70 to the inorganic layer 60. The adhesive layer 70 is not particularly limited as long as it allows the inorganic layer 60 to adhere to the light extraction substrate 80 and allows light from the luminescent layer to pass therethrough, and the adhesive layer may be selected from various types of resins such as UV-curable resin, thermosetting resin and thermoplastic resin. For further improving the light extraction efficiency, it is preferable that the adhesive layer 70 has a refractive index smaller than that of the inorganic layer 60 and is as near that of the light extraction substrate 80 as possible, and the refractive index of the adhesive layer is particularly preferably 1.3 to 1.6, more preferably 1.4 to 1.6. The adhesive layer 70 is not particularly limited as long as this condition is satisfied. However, from the viewpoint of low refractive index, formability, optical transparency, preferable examples of materials constituting the adhesive layer 70 include polymethyl methacrylate (PMMA, refractive index: 1.5), polyethylene (refractive index: 1.51), polyisobutene (refractive index: 1.51), polybutadiene (refractive index: 1.52), polyisoprene (refractive index: 1.52), polyacrolein (refractive index: 1.53), polyvinyl butyral (refractive index: 1.48 to 1.49), polyvinyl acetal (refractive index: 1.48 to 1.50), polyvinyl alcohol (refractive index: 1.49 to 1.53), UV-curable epoxy resin (refractive index: 1.53), thermosetting epoxy resin (refractive index: 1.54), UV-curable acrylic resin (refractive index: 1.48 to 1.52), polycarbonate resin (refractive index: 1.58), polyester resin (refractive index: 1.52 to 1.53), polystyrene resin (refractive index: 1.59) and polyimide resin (refractive index: 1.6).

The thickness of the adhesive layer 70 is usually 0.1 to 30 μm, preferably 0.5 to 20 μm, more preferably 1 to 20 μm, from the standpoint that the light extraction substrate 80 is certainly adhered to the inorganic layer 60 and optical transparency is not prevented.

Examples of the method of forming the adhesive layer 70 includes, but not limited to, those coating methods using any coating techniques such as knife coating, roll coating, curtain coating, spin coating, bar coating, dip coating, and spin coating. Alternatively, a thermosetting or thermoplastic adhesive sheet may be used.

### <Light Extraction Substrate>

The light extraction substrate 80 is attached via the adhesive layer 70 to the inorganic layer 60. The light extraction substrate 80 may be provided with the adhesive layer 70 and adhered to the inorganic layer 60 via the adhesive layer.

As the light extraction substrate 80, an optically transparent substrate is used and a glass substrate or a resin film can be preferably used.

The thickness of the light extraction substrate 80 is preferably 0.05 to 2 mm, from the viewpoint of optical transparency, strength, and weight reduction.

The light extraction substrate 80 formed of a resin film may use the same material as in the supporting substrate 20, such as PET, PEN or PES. When a resin film is used as the light extraction substrate 80, the resin film may be provided with a barrier layer to improve barrier properties. The thickness of the barrier layer may be determined depending on its material and required barrier properties, and is usually 100 nm to 5 μm, more preferably 1 82 m to 5 μm.

An electric source is connected to both the electrodes 30 and 50 respectively, and direct current (which may if necessary contain an alternating current component) voltage (usually 2 to 15 volts) or direct current is applied, whereby the luminescent layer sandwiched between the electrodes 30 and 50 can emit light. The driving method can use any of driving methods described in JP-A No. 2-148687, JP-A No. 6-301355, JP-A No. 5-29080, JP-A No. 7-134558, JP-A No. 8-234685, JP-A No. 8-241047, Japanese Patent No. 2784615, U.S. Pat. No. 5,828,429 and U.S. Pat. No. 6, 023,308.

In the organic electroluminescence panel 10 thus constituted, the inorganic layer 60 functions not only as a sealing layer but also as a light scattering layer. Accordingly, the organic electroluminescence panel with high light extraction efficiency can be easily produced without arranging another layer for conferring light scattering properties.

The organic electroluminescence panel according to the invention is preferably in the following modes:

The inorganic layer includes plural layers, and among the plural layers, a layer including the outermost surface at the light extraction side is a high-refractive-index layer having a refractive index of 2.1 to 3.0, and at least one of the other layers among the plural layers is a gas barrier layer having higher gas barrier properties than those of the high-refractive-index layer.

The gas barrier layer comprises SiON or SiN.

The high-refractive-index layer comprises TiO₂ or ZnS.

The refractive index of the adhesive layer is 1.3 to 1.6.

### EXAMPLES

### Example 1

An organic electroluminescence panel having the following element structure was manufactured. The thickness of each element is shown in parentheses.

A glass substrate (0.7 mm)/Ag electrode (200 nm)/organic layer (180 nm)/Ag (20 nm)/ITO electrode (100 nm)/inorganic layer (5.2 μm)/PMMA adhesive layer (10 μm)/glass substrate (0.7 mm)

The organic layer was formed in the following manner.

An Ag anode was formed in the form of a stripe of 200 nm in thickness and 2 mm in width on a glass substrate (25 mm×25 mm), and then a vacuum deposition apparatus was degassed to a vacuum degree of 5×10⁻⁵ Pa.

As a hole injection layer, 2-TNATA, and F4-TCNQ in an amount of 1.0% by mass relative to 2-TNATA, were co-deposited and formed at a thickness of 100 nm.

As a hole transport layer, NPD was then formed at a thickness of 10 nm.

After the hole transport layer was formed, CBP, and Ir(ppy)₃ in an amount of 5% by mass relative to CBP, were co-deposited to form a luminescent layer of 30 nm in thickness.

As an electron transport layer, BAlq was then formed at a thickness of 40 nm.

The layer structure of the inorganic layer is as follows:

SiN (1 μm)/SiON (3 μm)/SiN (1 μm)/TiO₂ (0.2 μm)

The inorganic layer was formed in the following manner.

An SiN film (refractive index: 2.0), an SiON film (refractive index: 1.8) and an SiN film (refractive index: 2.0) were formed by CVD, respectively.

Then, this specimen was introduced into a sputtering apparatus (trade name: ACS-4000-C3, manufactured by ULVAC, Inc.), and a TiO₂ film (refractive index: 2.5) was formed thereon. The TiO₂ film was provided with a concave-convex structure by sputtering (reverse sputtering, gas: argon) under the condition of a plasma potential of 20 V. When the concave-convex structure of the TiO₂ film was measured in accordance with JIS B0601:2001 by using a P-15 contact-type surface roughness meter manufactured by KLA-Tencor Japan, the surface roughness Ra was 120 nm (average height: 150 nm, average pitch: 130 nm).

The inorganic layer was coated with PMMA (thickness: 10 μm, refractive index: 1.5) as an adhesive layer to which the glass substrate (20 mm×20 mm) at the light extraction side was then attached. In this manner, an organic electroluminescence panel was manufactured.

### Example 2

An organic electroluminescence panel was manufactured in the same manner as in Example 1 except that a ZnS film (thickness: 0.3 μm, refractive index: 2.37) was formed in place of the TiO₂ film. The surface roughness Ra of the ZnS film was 150 nm.

### Comparative Example 1

An organic electroluminescence panel was manufactured in the same manner as in Example 1 except that an inorganic film having the same composition and film thickness as in Example 1 was formed as the inorganic film and then provided, without treatment by reverse sputtering, with an adhesive layer followed by attaching a glass substrate thereto.

### Comparative Example 2

An organic electroluminescence panel was manufactured in the same manner as in Example 1 except that no inorganic layer was formed.

### Examples 3 to 6

Organic electroluminescence panels in which Ra was respectively changed were manufactured in the same manner as in Example 1 except that the sputtering of the TiO₂ film in Example 1 was conducted under the condition of the plasma potentials shown in Table 1.

### <Evaluation of Light Extraction Efficiency>

An electric source was connected to the anode and cathode in each panel, then the panel was driven with a driving current of 2.5 mA/cm², and the front face of the organic EL panel was measured with a luminance meter CS-1000 (manufactured by KONICA MINOLTA Japan) to determine a peak intensity in its EL spectrum.

With respect to the organic EL panels obtained in the Examples and Comparative Examples, the material of the outermost surface of the inorganic layer, the surface roughness Ra of the outermost surface, and the measurement results of peak intensity, are shown in Table 1 below. The peak intensities in Table 1 are peak intensities of the luminescence panels in each of the Examples and Comparative Examples, wherein each peak intensity is expressed relative to the peak intensity of the luminescence panel in Comparative Example 1, which was designated as 1.

TABLE 1

| | | | | | | Peak |
|---|---|---|---|---|---|---|
| | Outermost Surface of Inorganic Layer | | | | | Intensity |
| | | Refractive | Sputtering | | | in EL |
| | Material | index | potential (V) | Ra | | Spectrum |
| Example 1 | TiO₂ | 2.50 | 20 | 120 | nm | 1.5 |
| Example 2 | ZnS | 2.37 | 20 | 150 | nm | 1.4 |
| Comparative | TiO₂ | 2.50 | — | 2 | nm | 1.0 |
| Example 1 | | | | | | |
| Comparative | — | — | — | — | | 0.8 |
| Example 2 | | | | | | |
| Example 3 | TiO₂ | 2.50 | 10 | 10 | nm | 1.3 |
| Example 4 | TiO₂ | 2.50 | 17 | 70 | nm | 1.4 |
| Example 5 | TiO₂ | 2.50 | 30 | 1.5 | μm | 1.3 |
| Example 6 | TiO₂ | 2.50 | 40 | 5.7 | μm | 1.2 |

Hereinabove, the invention has been described, but the invention is not limited to the exemplary embodiments and the examples described above.

For example, the luminescence panel according to the invention may be used as a backlight for a liquid crystal display or as a light source for an image forming apparatus, or may serve as a display device with a luminescence layer patterned in RGB to form pixels.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The exemplary embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

All publications, patent applications, and technical standards mentioned in this specification are herein incorporated by reference to the same extent as if each individual publication, patent application, or technical standard was specifically and individually indicated to be incorporated by reference.

What is claimed is:

1. An organic electroluminescence panel comprising:
a supporting substrate,
a lower electrode arranged on the supporting substrate,
an organic layer arranged on the lower electrode and including at least a luminescence layer,
an upper electrode arranged on the organic layer,
an inorganic layer which is arranged on the upper electrode, has a refractive index in the range of 1.7 to 3.0, and has a concave-convex structure having a surface roughness Ra of 10 nm to 10 μm formed at an outermost surface on a light extraction side,
an adhesive layer arranged on the inorganic layer, and
a light extraction substrate adhered via the adhesive layer to the inorganic layer.

2. The organic electroluminescence panel of claim 1, wherein the inorganic layer comprises a plurality of layers, and among the plurality of layers, a layer including the outermost surface at the light extraction side is a high-refractive-index layer having a refractive index of 2.1 to 3.0, and at least one of the other layers among the plurality of layers is a gas barrier layer having higher gas barrier properties than those of the high-refractive-index layer.

3. The organic electroluminescence panel of claim 2, wherein the gas barrier layer comprises SiON or SiN.

4. The organic electroluminescence panel of claim 2, wherein the high-refractive-index layer comprises TiO₂ or ZnS.

5. The organic electroluminescence panel of claim 3, wherein the high-refractive-index layer comprises TiO₂ or ZnS.

6. The organic electroluminescence panel of claim 1, wherein the refractive index of the adhesive layer is 1.3 to 1.6.

7. The organic electroluminescence panel of claim 5, wherein the refractive index of the adhesive layer is 1.3 to 1.6.

8. A method for manufacturing the organic electroluminescence panel of claim 1, comprising:
forming an inorganic film on the upper electrode, and
sputtering the outermost surface, at the light extraction side, of the inorganic film, thereby providing the outermost surface with a concave-convex structure.
